(19) United States
(12) Patent Application Publication
(10) Pub. No.: US 2023/0035382 A1
(43) Pub. Date: Feb. 2, 2023

(54) ADHESIVE COMPOSITION

(71) Applicant: SHIN-ETSU POLYMER CO., LTD., Chiyoda-ku, Tokyo (JP)

(72) Inventors: Wataru KATAGIRI, Saitama (JP); Shiori MOMMA, Saitama (JP)

(21) Appl. No.: 17/757,771

(22) PCT Filed: Oct. 19, 2020
(86) PCT No.: PCT/JP2020/039251

§ 371 Date: Jun. 20, 2022

(30) Foreign Application Priority Data
Dec. 23, 2019 (JP) 2019-231705

(51) Int. Cl. C09J 163/04; C09J 11/06; C09J 7/35

(52) U.S. Cl. CPC C09J 163/04; C09J 11/06; C09J 7/35; C09J 2463/00; C09J 2461/006

(57) ABSTRACT

Provided is an adhesive composition that is capable of forming an adhesive layer having excellent electrical properties (low relative permittivity and low dielectric loss tangent) and excellent adhesiveness (adhesion properties) after heat curing, can improve adhesiveness (adhesion properties) in a laminating step, can prevent the peeling and lifting of layers during temporary fixing and roll-to-roll work, also has a high crosslink density, and does not cause heat resistance, solvent resistance and the like to deteriorate. The adhesive composition contains a bismaleimide resin and a styrene-based elastomer.

### TECHNICAL FIELD

The present invention relates to an adhesive composition. More specifically, the present invention relates to an adhesive composition that can be used for adhesive applications of electronic parts and the like.

### BACKGROUND ART

As electronic devices become more compact and lightweight, bonding applications of electronic parts and the like are diversifying, and the demand for laminated bodies provided with an adhesive layer is increasing.

Further, for flexible printed circuit boards (hereinafter, also referred to as FPCs), which are one type of electronic part, there is a need to process large amounts of data at high speed, and so support for high frequencies is progressing. To increase the frequency of FPCs, it is necessary to reduce the dielectric of the components, and low-dielectric base films and low-dielectric adhesives are being developed.

However, low-dielectric adhesives have low molecular polarity, so it is difficult to exhibit adhesiveness (adhesion properties) with the base film and other components related to electronic parts. Moreover, low-dielectric base films also similarly have poor adhesiveness (adhesion properties) with adhesives, and so there is a need for improvement in adhesiveness.

Therefore, in order to achieve high adhesion properties while having good electrical properties (low relative permittivity and low dielectric loss tangent), a laminate composed of an adhesive layer composed of an adhesive composition and a base film, with the adhesive composition containing a carboxy group-containing styrene-based elastomer (A) and an epoxy resin (B), has been proposed (see, for example, Patent Literature 1).

### CITATION LIST

### Patent Literature

Patent Literature 1: International Publication No. 2016/017473

### SUMMARY OF INVENTION

### Technical Problem

However, although the adhesive composition described in Patent Literature 1 exhibits, to some extent, high adhesiveness (adhesion properties) after heat curing, there is still room for improvement in terms of improving adhesiveness (adhesion properties).

Further, it was also found that in the process of producing a laminate, when the laminating step has a short heating time, in some cases pressure-sensitive adhesion to the base film and other components related to electronic parts is not sufficient.

In the laminating step, if the adhesive composition is not sufficiently pressure-sensitively adhered to the base film and other components related to electronic parts, in the production of the laminate, the layers peel or lift up during temporary fixing when laminating by thermocompression bonding or during roll-to-roll work. As a result, lamination defects occur, and because there are gaps due to fine irregularities occurring between the layers, swelling of the layers occurs in the subsequent heating step, and various problems in laminate occur.

Moreover, although an adhesive composition can have improved pressure-sensitive adhesion properties by containing an additive having a low softening point or melting point, a pressure-sensitive adhesion imparting agent having no reactive groups does not crosslink and therefore heat resistance deteriorates, while on the other hand a low molecular weight resin having a reactive group (epoxy resins and the like) causes electrical properties (low relative permittivity and low dielectric loss tangent) to deteriorate.

Accordingly, it is an object of the present invention to provide an adhesive composition that is capable of forming an adhesive layer having excellent electrical properties (low relative permittivity and low dielectric loss tangent) and excellent adhesiveness (adhesion properties) after heat curing, can improve adhesiveness (adhesion properties) in a laminating step, can prevent the peeling and lifting of layers during temporary fixing and roll-to-roll work, also has a high crosslink density, and does not cause heat resistance, solvent resistance and the like to deteriorate.

### Solution to Problem

As a result of diligent research to solve the above-mentioned problems, the present inventors have discovered that an adhesive composition containing a bismaleimide resin and a styrene-based elastomer exhibits excellent electrical properties, and after heat curing, exhibits high adhesiveness (adhesion properties) to a base film, as well as sufficient adhesiveness (adhesion properties) to the base film in a laminating step, also has a high crosslink density, does not cause heat resistance, solvent resistance and the like to deteriorate, and could solve the above-mentioned problems, thereby completing the present invention.

The present invention includes the following aspects.

[1] An adhesive composition comprising a bismaleimide resin and a styrene-based elastomer.
[2] The adhesive composition according to [1], further comprising an epoxy resin.
[3] The adhesive composition according to [2], wherein a content of the epoxy resin is 1 to 20 parts by mass based on 100 parts by mass of the adhesive composition.
[4] The adhesive composition according to any one of [1] to [3], further comprising an organic peroxide.
[5] The adhesive composition according to any one of [1] to [4], wherein the styrene-based elastomer is any one or both of an amino group-containing styrene-based elastomer and a carboxy group-containing styrene-based elastomer.
[6] The adhesive composition according to [5], wherein a total amount of nitrogen in the amino group-containing styrene-based elastomer is 50 to 5,000 ppm.
[7] The adhesive composition according to any one of [2] to [6], wherein the epoxy resin has a softening point or a melting point of 90° C. or lower.
[8] The adhesive composition according to any one of [2] to [7], wherein the epoxy resin is a novolak type epoxy resin.
[9] The adhesive composition according to any one of [2] to [7], wherein the epoxy resin is a glycidylamine type epoxy resin.
[10] The adhesive composition according to any one of [2] to [7], wherein the epoxy resin is an epoxy compound of a styrene-butadiene block copolymer.
[11] An adhesive layer obtained by curing the adhesive composition according to any one of [1] to [10], wherein the adhesive layer has a relative permittivity of 3.5 or less and a dielectric loss tangent of 0.01 or less when measured at a frequency of 28 GHz.
[12] A laminate comprising:

a base film; and

an adhesive layer composed of the adhesive composition according to any one of [1] to [10], or the adhesive layer according to [11]. [13] The laminate according to [12], wherein the base film contains a polyether ether ketone (PEEK) resin.

[14] A coverlay film provided with an adhesive layer, comprising the laminate according to [12] or [13].
[15] A copper-clad laminate comprising the laminate according to [12] or [13].
[16] A printed circuit board comprising the laminate according to [12] or [13].
[17] A shield film comprising the laminate according to [12] or [13].
[18] A printed circuit board provided with a shield film, comprising the laminate according to [12] or [13].

### Advantageous Effects of Invention

According to the present invention, provided is an adhesive composition that is capable of forming an adhesive layer having excellent electrical properties (low relative permittivity and low dielectric loss tangent) and excellent adhesiveness (adhesion properties) after heat curing, can improve adhesiveness (adhesion properties) in a laminating step, can prevent the peeling and lifting of layers during temporary fixing and roll-to-roll work, also has a high crosslink density, and does not cause heat resistance, solvent resistance and the like to deteriorate.

### DESCRIPTION OF EMBODIMENTS

Hereinafter, the adhesive composition of the present invention, the laminate including an adhesive layer composed of the adhesive composition, and electronic-parts-related components including the laminate will be described in detail, but the following description of the constituent requirements is one example of an embodiment of the present invention, and the present invention is not limited to the subject matters described here.

(Adhesive Composition)

The adhesive composition of the present invention contains a bismaleimide resin and a styrene-based elastomer. The adhesive composition of the present invention can, optionally, further contain an epoxy resin. In addition, the adhesive composition of the present invention can, optionally, contain other components.

The adhesive composition of the present invention containing a bismaleimide resin and a styrene-based elastomer exhibits high adhesiveness (adhesion properties) even in a low-dielectric adhesive composition, and also exhibits excellent adhesiveness (adhesion properties) in a laminating step. In addition, since it has a high crosslink density, the adhesive composition of the present invention does not cause heat resistance, solvent resistance and the like to deteriorate.

<Bismaleimide Resin>

Bismaleimide resins are low-dielectric resins that have a low softening point, but generally have poor compatibility with other resins. However, the present inventors discovered that bismaleimide resins can mix well with styrene-based elastomers, and that an adhesive composition having a bismaleimide resin and a styrene-based elastomer can exhibit good adhesiveness (adhesion properties) in the laminating step.

Further, bismaleimide resins have an unsaturated bond and are capable of crosslinking. The adhesive composition of the present invention containing a bismaleimide resin has a high crosslink density and does not cause heat resistance, solvent resistance, and the like to deteriorate.

Examples of the bismaleimide resin include 1-methyl-2,4-bismaleimidebenzene, N,N′-m-phenylenebismaleimide, N,N′-p-phenylenebismaleimide, N,N′-m-toluylenebismaleimide, N,N′-4,4-biphenylenebismaleimide, N,N′-4,4-(3,3′-dimethyl-biphenylene)bismaleimide, N,N′-4,4-(3,3′-dimethyldiphenylmethane)bismaleimide, N,N′-4,4-(3,3′-diethyldiphenylmethane)bismaleimide, N,N′-4,4-diphenylmethanebismaleimide, N,N′-4,4-diphenylpropanebismaleimide, N,N′-4,4-diphenyletherbismaleimide and N,N′-3,3-diphenylsulfonebismaleimide.

The content of the bismaleimide resin is preferably 5 parts by mass to 70 parts by mass based on 100 parts by mass of the solid content of the adhesive composition. When the content of the bismaleimide resin is equal to or more than this lower limit value, pressure-sensitive adhesion properties can be imparted to the adhesion properties composition. On the other hand, when the content is equal to or less than this upper limit value, the time required for curing can be shortened.

<Styrene-Based Elastomer>

The styrene-based elastomer is a copolymer mainly composed of blocks and random structures of a conjugated diene compound and an aromatic vinyl compound, or hydrogenated products thereof.

The styrene-based elastomer can be a modified styrene-based elastomer or an unmodified styrene-based elastomer, and can be selected according to the intended purpose without any particular limitation. In the present invention, a modified styrene-based elastomer, including the styrene-based elastomers containing an amino group and the styrene-based elastomers containing a carboxy group described below, are more preferable.

The styrene-based elastomers can be used singly, or in combinations of two or more.

Examples of preferable aspects of the adhesive composition of the present invention include an adhesive composition containing a bismaleimide resin and an amino group-containing styrene-based elastomer, an adhesive composition containing a bismaleimide resin and a carboxy group-containing styrene-based elastomer, and an adhesive composition containing a bismaleimide resin, an amino group-containing styrene-based elastomer, and a carboxy group-containing styrene-based elastomer.

<Amino Group-Containing Styrene-Based Elastomer>

The imide skeleton of the bismaleimide resin has good compatibility with amino groups, and among styrene-based elastomers, an amino group-containing styrene-based elastomer enables to achieve even better compatibility with the adhesive composition.

The adhesive composition containing an amino group-containing styrene-based elastomer improves the adhesiveness of the adhesive layer, and in particular, improves the adhesiveness with a metal.

Further, as described later, when the adhesive composition of the present invention further contains an epoxy resin, the amino group-containing styrene-based elastomer is reactive, and therefore the heat resistance and chemical resistance of the adhesive layer are improved by epoxy curing. In addition, the amino group reacts with the epoxy group to initiate polymerization, so that the reaction rate is further improved.

The amino group-containing styrene-based elastomer is an elastomer obtained by modifying, with an amine, a copolymer mainly composed of blocks and random structures of a conjugated diene compound and an aromatic vinyl compound, or hydrogenated products thereof.

Examples of the aromatic vinyl compound include styrene, t-butylstyrene, α-methylstyrene, divinylbenzene, 1,1-diphenylethylene, N,N-diethyl-p-aminoethylstyrene and vinyltoluene. Examples of the conjugated diene compound include butadiene, isoprene, 1,3-pentadiene and 2,3-dimethyl-1,3-butadiene.

The method for modifying the styrene-based elastomer with an amine is not particularly limited, and a known method can be used. Examples of the method include an amine-modification method in which a polymerization initiator having an amino group is used to polymerize a (hydrogenated) block copolymer, an amine-modification method in which a (hydrogenated) copolymer is modified by using an unsaturated monomer having an amino group with a raw material for copolymerization, and an amine-modification method in which an amine modifier having two or more amino groups is reacted with a carboxy group-containing styrene-based elastomer to form an amide structure or an imide structure.

Further, the weight average molecular weight of the amino group-containing styrene-based elastomer is preferably 10,000 to 500,000, more preferably 30,000 to 300,000, and further preferably 50,000 to 200,000. When the weight average molecular weight is equal to or more than this lower limit, excellent adhesion properties can be exhibited, and coating properties when dissolved in a solvent and applied are also improved. When the weight average molecular weight is equal to or less than this upper limit, compatibility with the bismaleimide resin or the epoxy resin is improved.

The weight average molecular weight is a value calculated by converting the molecular weight measured by gel permeation chromatography (hereinafter, also referred to as “GPC”) based on polystyrene.

Specific examples of the amino group-containing styrene-based elastomer include elastomers obtained by modifying, with a compound having an amino group, a styrene-butadiene block copolymer, a styrene-ethylene propylene block copolymer, a styrene-butadiene-styrene block copolymer, a styrene-isoprene-styrene block copolymer, a styrene-ethylene butylene-styrene block copolymer, a styrene-ethylene propylene-styrene block copolymer, and the like.

These amino group-containing styrene-based elastomers can be used singly or in combinations of two or more

Among the above-mentioned copolymers, preferable from the viewpoint of adhesion properties and electrical properties are a styrene-ethylene butylene-styrene block copolymer and a styrene-ethylene propylene-styrene block copolymer.

Further, the mass ratio of styrene/ethylene butylene in the styrene-ethylene butylene-styrene block copolymer and the mass ratio of styrene/ethylene propylene in the styrene-ethylene propylene-styrene block copolymer are preferably 10/90 to 50/50, and more preferably 20/80 to 40/60. When the mass ratio is within this range, an adhesive composition having excellent adhesive properties can be obtained.

The content of the amino group-containing styrene-based elastomer is preferably 15 to 90 parts by mass based on 100 parts by mass of the solid content of the adhesive composition. When the content is within this range, an adhesive composition having excellent adhesive properties can be obtained.

From the viewpoint of ensuring a low relative permittivity and the adhesiveness (adhesion properties) of the adhesive composition, the total amount of nitrogen in the amino group-containing styrene-based elastomer is preferably 50 to 5,000 ppm, and more preferably 200 to 3,000 ppm. When the total amount of nitrogen is equal to or higher than this lower limit, excellent adhesiveness can be exhibited. When the total amount of nitrogen is equal to or less than this upper limit, the electrical properties are excellent.

The total amount of nitrogen in the amino group-containing styrene-based elastomer can be determined according to JIS-K2609 using a trace nitrogen analyzer, model ND-100 (manufactured by Mitsubishi Chemical Corporation), for example.

<Carboxy Group-Containing Styrene-Based Elastomer>

The carboxy group-containing styrene-based elastomer is effective as a component for imparting electrical properties in addition to adhesion properties and flexibility of the cured product.

The adhesive composition containing a carboxy group-containing styrene-based elastomer improves the adhesiveness of the adhesive layer.

Further, as described later, when the adhesive composition of the present invention further contains an epoxy resin, the carboxy group-containing styrene-based elastomer is reactive, and therefore the heat resistance and chemical resistance of the adhesive layer are also improved by epoxy curing. The carboxy group is less reactive with an epoxy resin than the amino group, and therefore the retention period of the B-stage adhesive composition can be lengthened.

The carboxy group-containing styrene-based elastomer is an elastomer obtained by modifying, with an unsaturated carboxylic acid, a copolymer mainly composed of blocks and random structures of a conjugated diene compound and an aromatic vinyl compound, or hydrogenated products thereof.

Examples of the aromatic vinyl compound include styrene, t-butylstyrene, α-methylstyrene, divinylbenzene, 1,1-diphenylethylene, N,N-diethyl-p-aminoethylstyrene and vinyltoluene. Examples of the conjugated diene compound include butadiene, isoprene, 1,3-pentadiene and 2,3-dimethyl-1,3-butadiene.

The modification of the carboxy group-containing styrene-based elastomer can be conducted by, for example, copolymerizing an unsaturated carboxylic acid during polymerization of the styrene-based elastomer. Further, the modification can also be conducted by heating and kneading the styrene-based elastomer and an unsaturated carboxylic acid in the presence of an organic peroxide.

Examples of the unsaturated carboxylic acid include acrylic acid, methacrylic acid, maleic acid, itaconic acid, fumaric acid, maleic anhydride and itaconic anhydride.

The amount to be modified by the unsaturated carboxylic acid is preferably 0.1 to 10% by mass.

The acid value of the carboxy group-containing styrene-based elastomer is preferably 0.1 to 25 mg KOH/g, and more preferably 0.5 to 23 mg KOH/g. When the acid value is 0.1 mg KOH/g or more, the adhesive composition can be cured sufficiently to achieve good adhesion properties and heat resistance. On the other hand, when the acid value is 25 mg KOH/g or less, adhesion strength and electrical properties are excellent.

The weight average molecular weight of the carboxy group-containing styrene-based elastomer is preferably 10,000 to 500,000, more preferably 30,000 to 300,000, and further preferably 50,000 to 200,000. When the weight average molecular weight is equal to or more than this lower limit, excellent adhesion properties can be exhibited, and coating properties when dissolved in a solvent and applied are also improved. When the weight average molecular weight is equal to or less than this upper limit, compatibility with the bismaleimide resin or the epoxy resin is improved.

Specific examples of the carboxy group-containing styrene-based elastomer include elastomers obtained by modifying, with an unsaturated carboxylic acid, a styrene-butadiene block copolymer, a styrene-ethylene propylene block copolymer, a styrene-butadiene-styrene block copolymer, a styrene-isoprene-styrene block copolymer, a styrene-ethylene butylene-styrene block copolymer, a styrene-ethylene propylene-styrene block copolymer, and the like.

These carboxy group-containing styrene-based elastomers can be used singly or in combinations of two or more. Among the above-mentioned copolymers, preferable from the viewpoint of adhesion properties and electrical properties are a styrene-ethylene butylene-styrene block copolymer and a styrene-ethylene propylene-styrene block copolymer. Further, the mass ratio of styrene/ethylene butylene in the styrene-ethylene butylene-styrene block copolymer and the mass ratio of styrene/ethylene propylene in the styrene-ethylene propylene-styrene block copolymer are preferably 10/90 to 50/50, and more preferably 20/80 to 40/60. When the mass ratio is within this range, an adhesive composition having excellent adhesive properties can be obtained.

The content of the carboxy group-containing styrene-based elastomer is preferably 15 to 90 parts by mass based on 100 parts by mass of the solid content of the adhesive composition. When the content is within this range, an adhesive composition having excellent adhesive properties can be obtained.

<Epoxy Resin>

As described above, the adhesive composition of the present invention preferably further contains an epoxy resin.

By incorporating the unsaturated bond of bismaleimide through anionic polymerization of the epoxy resin, the crosslinking reaction can be promoted at a low temperature.

The epoxy resin is effective as a component for reacting with the modified amino group- or carboxy group-containing styrene-based elastomer to realize high adhesion properties to adherends and heat resistance of the cured product of the adhesive.

Examples of the epoxy resin include, but are not limited to, a bisphenol A type epoxy resin, a bisphenol F type epoxy resin, or a hydrogenated product thereof; glycidyl ester type epoxy resins, including diglycidyl phthalate, diglycidyl isophthalate, diglycidyl terephthalate, glycidyl p-hydroxybenzoate, diglycidyl tetrahydrophthalate, diglycidyl succinate, diglycidyl adipate, diglycidyl sebacate and triglycidyl trimellitate; glycidyl ether type epoxy resins, including ethylene glycol diglycidyl ether, propylene glycol diglycidyl ether, 1,4-butanediol diglycidyl ether, 1,6-hexanediol diglycidyl ether, trimethylolpropane triglycidyl ether, pentaerythritol tetraglycidyl ether, tetraphenylglycidylether ethane, triphenylglycidylether ethane, polyglycidyl ethers of sorbitol, and polyglycidyl ethers of polyglycerol; glycidylamine type epoxy resins, including triglycidyl isocyanurate and tetraglycidyl diaminodiphenylmethane; and linear aliphatic epoxy resins, including epoxidized polybutadiene and epoxidized soybean-oil. Also usable are novolak type epoxy resins, including a xylene-structure-containing novolak epoxy resin, a naphthol novolak type epoxy resin, a phenol novolak epoxy resin, an o-cresol novolak epoxy resin, and bisphenol A novolak epoxy resin.

Further, examples of the usable epoxy resins include a brominated bisphenol A type epoxy resin, a phosphorus-containing epoxy resin, a fluorine-containing epoxy resin, an epoxy resin containing a dicyclopentadiene skeleton, an epoxy resin containing a naphthalene skeleton, an anthracene type epoxy resin, a tertiary butylcatechol type epoxy resin, a triphenylmethane type epoxy resin, a tetraphenylethane type epoxy resin, a biphenyl type epoxy resin and a bisphenol S type epoxy resin. These epoxy resins can be used singly or in combinations of two or more.

Among the above epoxy resins, an epoxy resin not having a hydroxyl group is preferable because an adhesive composition having excellent electrical properties can be obtained and compatibility with the styrene-based elastomer is good. In particular, a novolak epoxy resin or an epoxy resin having the following structure are more preferable because they are epoxy resins having an appropriately flexible skeleton, and therefore brittle fracture of the cured product is less likely to occur, the performance stability of the cured product of the adhesive composition in long-term usage is improved, and heat resistance is also improved due to a high number of functional groups.

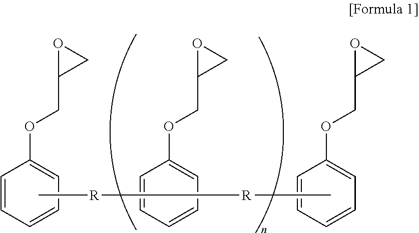

R is a structure including methylene-aryl-methylene or a structure including an aliphatic hydrocarbon structure having six or more carbon atoms, examples of the aryl include benzene, xylene, naphthalene and biphenyl, and examples of the aliphatic hydrocarbon include hexane, dimethylcyclohexane and dicyclopentadiene.

Specific examples of the novolak type epoxy resin include “YX7700” (novolak type epoxy resin containing a xylene structure) manufactured by Mitsubishi Chemical Corporation, “NC7000L” (naphthol novolak type epoxy resin) manufactured by Nippon Kayaku Co., Ltd., “ESN485” (naphthol novolak type epoxy resin) manufactured by Nippon Steel Chemical & Material Co., Ltd., “N-690” (cresol novolac type epoxy resin) manufactured by DIC Corporation, and “N-695” (cresol novolak type epoxy resin) manufactured by DIC Corporation. More preferably, the novolak type epoxy resin is an epoxy compound of a styrene-butadiene block copolymer. Epoxy compounds of styrene-butadiene block copolymers can accelerate the reaction rate and increase the crosslink density by involvement of unsaturated bonds in addition to aromatic rings like an olefin skeleton and a vinyl group in the reaction of the epoxy structure, and as a result, heat resistance and chemical resistance can be improved even with a small amount to be blended. Further, epoxy compounds of the styrene-butadiene block copolymers have a large molecular weight and include an epoxy group, and therefore act like a dispersant and further improve the dispersibility of the inorganic filler. As the epoxy compound of a styrene-butadiene block copolymer, a commercially available epoxy compound can be used, and examples thereof include Celloxide 2021P, Celloxide 2081 and Celloxide 2000 (manufactured by Daicel Corporation), Epolead GT401, Epolead PB3600 and Epolead PB4700 (manufactured by Daicel Corporation), and Epofriend AT501 and Epofriend CT310 (manufactured by Daicel Corporation).

Further, the epoxy resin having an amino group can shorten the curing time and lower the curing temperature based on the catalytic action of the amino group, and therefore workability can be improved. In addition, since an amine group is included, the adhesiveness with a metal layer is improved.

In particular, a glycidylamine type epoxy resin is more preferable as the epoxy resin. Glycidylamine type epoxy resins are polyfunctional, and therefore curing is possible with a small amount, and since an amine is included in the molecular skeleton, compatibility with an amino group-containing styrene-based elastomer is good and there is also a reaction promoting effect. Moreover, since glycidylamine type epoxy resins include an amine group, adhesiveness with a metal layer can be improved.

Specific examples of the glycidylamine type epoxy resin include as a tetraglycidyldiaminodiphenylmethane, “jER604” manufactured by Mitsubishi Chemical Corporation, “Sumi-Epoxy ELM434” manufactured by Sumitomo Chemical Co., Ltd., “Araldite MY720,” “Araldite MY721,” “Araldite MY9512,” “Araldite MY9612,” “Araldite MY9634” and “Araldite MY9663” manufactured by Huntsman Advanced Materials, and “TETRAD-X” and “TETRAD-C” manufactured by Mitsubishi Gas Chemical Company, Inc.

The epoxy resin used in the present invention preferably has two or more epoxy groups in one molecule. This is because a crosslinked structure can be formed by reaction with a styrene-based elastomer, particularly a modified styrene-based elastomer, and high heat resistance can be exhibited. Further, when an epoxy resin having two or more epoxy groups is used, the degree of crosslinking with the modified styrene-based elastomer is sufficient, and sufficient heat resistance can be obtained.

The content of the epoxy resin is preferably 1 to 20 parts by mass based on 100 parts by mass of the solid content of the adhesive composition. When the content of the epoxy resin is equal to or more than this lower limit value, the adhesive composition can be sufficiently cured, and good heat resistance and chemical resistance can be ensured. On the other hand, if the content of the epoxy resin is high, adhesiveness deteriorates and therefore, when the content is equal to or less than this upper limit value, good adhesiveness can be ensured. If the content of the epoxy resin is high, it is not possible to achieve an improvement in the adhesiveness (pressure-sensitive adhesion properties) in the laminating step. Further, since the epoxy resin has a high dielectric constant, if the content is equal to or less than the upper limit value, it is possible to prevent an increase in the dielectric constant of the adhesive composition.

The softening point or melting point of the epoxy resin is preferably 90° C. or lower. It is preferable that the epoxy resin is dissolved at the reaction temperature because the reaction is fast.

<Other Components>

The adhesive composition can optionally contain an epoxy resin in addition to the above-mentioned styrene-based elastomers including the amino group-containing styrene-based elastomer and the carboxy group-containing styrene-based elastomer, and the above-mentioned bismaleimide resin. In addition, the adhesive composition can contain a thermoplastic resin other than a styrene-based elastomer, a pressure-sensitive adhesion imparting agent, a flame retardant, a curing agent, a curing accelerator, a coupling agent, a heat aging inhibitor, a leveling agent, a defoaming agent, an inorganic filler, a pigment, a solvent, and the like, to an extent that does not affect the function of the adhesive composition.

An example of a preferable embodiment of the adhesive composition containing other components is an adhesive composition containing an organic peroxide. The adhesive composition containing an organic peroxide enables to crosslink the bismaleimide resin even by radical polymerization, and to further improve the adhesiveness (adhesion properties), heat resistance and chemical resistance of the adhesive layer.

As the organic peroxide, an organic peroxide generally known as a radical polymerization initiator can be used, and examples of the organic peroxide include benzoyl peroxide, lauroyl peroxide, t-butyl peroxypivalate, t-butyl peroxyethylhexanoate, 1,1′-bis-(t-butylperoxy)cyclohexane, t-amylperoxy-2-ethylhexanoate and t-hexylperoxy-2-ethylhexanoate.

Of the above-mentioned other components, examples of another thermoplastic resin include phenoxy resins, polyamide resins, polyester resins, polycarbonate resins, polyphenylene oxide resins, polyurethane resins, polyacetal resins, polyethylene resins, polypropylene resins and polyvinyl resins. These thermoplastic resins can be used singly or in combinations of two or more.

Examples of the pressure-sensitive adhesion imparting agent include coumarone-indene resins, terpene resins, terpene-phenol resins, rosin resins, p-t-butylphenol-acetylene resins, phenol-formaldehyde resins, xylene-formaldehyde resins, petroleum-based hydrocarbon resins, hydrogenated hydrocarbon resins and turpentine-based resins. These pressure-sensitive adhesion imparting agents can be used singly or in combinations of two or more.

The flame retardant can be either an organic flame retardant or an inorganic flame retardant. Examples of organic flame retardants include: phosphorus-based flame retardants, including melamine phosphate, melamine polyphosphate, guanidine phosphate, guanidine polyphosphate, ammonium phosphate, ammonium polyphosphate, ammonium phosphate amide, ammonium polyphosphate amide, carbamoyl phosphate, carbamoyl polyphosphate, aluminum trisdiethylphosphinate, aluminum trismethylethylphosphinate, aluminum trisdiphenylphosphinate, zinc bisdiethylphosphinate, zinc bismethylethylphosphinate, zinc bisdiphenylphosphinate, titanyl bisdiethylphosphinate, titanium tetrakisdiethylphosphinate, titanyl bismethylethylphosphinate, titanium tetrakismethylethylphosphinate, titanyl bisdiphenylphosphinate and titanium tetrakisdiphenylphosphinate; nitrogen-based flame retardants, including triazine compounds like melamine, melam and melamine cyanurate, cyanuric acid compounds, isocyanuric acid compounds, triazole compounds, tetrazole compounds, diazo compounds and urea; and silicon-based flame retardants, including silicone compounds and silane compounds. Examples of inorganic flame retardants include metal hydroxides, including aluminum hydroxide, magnesium hydroxide, zirconium hydroxide, barium hydroxide and calcium hydroxide; metal oxides, including tin oxide, aluminum oxide, magnesium oxide, zirconium oxide, zinc oxide, molybdenum oxide and nickel oxide; and zinc carbonate, magnesium carbonate, barium carbonate, zinc borate and hydrated glass. These flame retardants can be used in combinations of two or more.

Examples of the curing agent include, but are not limited to, amine-based curing agents and acid anhydride-based curing agents. Examples of amine-based curing agents include melamine resins, including methylated melamine resin, butylated melamine resin and benzoguanamine resin; dicyandiamide and 4,4′-diphenyldiaminosulfone. Examples of acid anhydrides include aromatic acid anhydrides and aliphatic acid anhydrides. These curing agents can be used singly or in combinations of two or more.

The content of the curing agent is preferably 0.05 to 100 parts by mass, and more preferably 5 to 70 parts by mass, based on 100 parts by mass of the adhesive composition.

When the adhesive composition contains an epoxy resin, for example, the curing accelerator is used for the intended purpose of accelerating a reaction between the styrene-based elastomer, in particular a modified styrene-based elastomer, and the epoxy resin, and a reaction between the epoxy resin and the bismaleimide resin. Tertiary amine-based curing accelerators, tertiary amine salt-based curing accelerators, imidazole-based curing accelerators and the like can be used.

Examples of the tertiary amine-based curing accelerator include benzyldimethylamine, 2-(dimethylaminomethyl)phenol, 2,4,6-tris(dimethylaminomethyl)phenol, tetramethylguanidine, triethanolamine, N,N′-dimethylpiperazine, triethylenediamine and 1,8-diazabicyclo[5.4.0]undecene.

Examples of the tertiary amine salt-based curing accelerator include a formic acid salt, an octylic acid salt, a p-toluenesulfonic acid salt, an o-phthalic acid salt, a phenol salt or a phenol novolak resin salt of 1,8-diazabicyclo[5.4.0] undecene, as well as a formic acid salt, an octylic acid salt, a p-toluenesulfonic acid salt, an o-phthalic acid salt, a phenol salt or a phenol novolak resin salt of 1,5-diazabicyclo[4.3.0] nonene.

Examples of the imidazole-based curing accelerator include 2-methylimidazole, 2-undecylimidazole, 2-heptadecylimidazole, 1,2-dimethylimidazole, 2-methyl-4-ethylimidazole, 2-phenylimidazole, 2-phenyl-4-methylimidazole, 1-benzyl-2-methylimidazole, 1-benzyl-2-phenylimidazole, 2,4-diamino-6-[2′-methylimidazolyl-(1′)]ethyl-s-triazine, 2,4-diamino-6-[2′-undecylimidazolyl-(1′)]ethyl-s-triazine, 2,4-diamino-6-[2′-ethyl-4′-methylimidazolyl-(1′)]ethyl-s-triazine, 2,4-diamino-6-[2′-methylimidazolyl-(1′)]ethyl-s-triazine isocyanurate adduct, 2-phenylimidazole isocyanurate adduct, 2-phenyl-4,5-dihydroxymethylimidazole and 2-phenyl-4-methyl-5-hydroxymethylimidazole. These curing accelerators can be used singly or in combinations of two or more.

When the adhesive composition contains a curing accelerator, the content of the curing accelerator is preferably 0.05 to 10 parts by mass, and more preferably 0.1 to 5 parts by mass, based on 100 parts by mass of the adhesive composition. When the content of the curing accelerator is within this range, the reaction between the epoxy resin and the bismaleimide resin can easily proceed, and adhesion properties and heat resistance can be easily ensured.

Examples of the coupling agent include: silane-based coupling agents, including vinyltrimethoxysilane, 3-glycidoxypropyltrimethoxysilane, p-styryltrimethoxysilane, 3-methacryloxypropylmethyldimethoxysilane, 3-acryloxypropyltrimethoxysilane, N-2-(aminoethyl)-3-aminopropylmethyldimethoxylsilane, 3-ureidopropyltriethoxysilane, 3-mercaptopropylmethyldimethoxysilane, bis(triethoxysilylpropyl)tetrasulfide, 3-isocyanatopropyltriethoxysilane and imidazole silane; titanate-based coupling agents; aluminate-based coupling agents; and zirconium-based coupling agents. These can be used singly or in combinations of two or more.

Examples of the heat aging inhibitor include phenol-based antioxidants, including 2,6-di-tert-butyl-4-methylphenol, n-octadecyl-3-(3′,5′-di-tert-butyl-4′-hydroxyphenyl)propionate, tetrakis[methylene-3-(3,5-di-tert-butyl-4-hydroxyphenyl) propionate]methane, pentaerythritol tetrakis[3-(3,5-di-t-butyl-4-hydroxyphenol and triethylene glycol-bis[3-(3-t-butyl-5-methyl-4-hydroxyphenyl)propionate; sulfur-based antioxidants, including dilauryl-3,3′-thiodipropionate and dimyristyl-3,3′-dithiopropionate; and phosphorus-based antioxidants, including trisnonylphenylphosphite and tris(2,4-di-tert-butylphenyl)phosphite. These can be used singly or in combinations of two or more.

Examples of the inorganic filler include powders composed of titanium oxide, aluminum oxide, zinc oxide, carbon black, silica, talc, copper and silver. These can be used singly or in combinations of two or more.

(Adhesive Layer)

The adhesive layer of the present invention is composed of the above-mentioned adhesive composition of the present invention.

The adhesive composition that forms the adhesive layer can be cured.

The curing method is not particularly limited, and can be appropriately selected according to the intended purpose. Examples of the curing method include heat curing.

The thickness of the adhesive layer is not particularly limited, and can be appropriately selected according to the intended purpose. For example, the thickness is preferably 3 to 100 μm, more preferably 5 to 70 μm, and further preferably 10 to 50 μm.

<Method for Producing Adhesive Layer>

The adhesive layer can be produced by forming the adhesive composition as a film.

The adhesive composition can be produced by mixing the bismaleimide resin, the styrene-based elastomer, optionally the epoxy resin, and optionally the other components. The mixing method is not specifically limited so long as a uniform adhesive composition is obtained. Since the adhesive composition is preferably used in the form of a solution or a dispersion, a solvent is generally used.

Examples of the solvent include alcohols, including methanol, ethanol, isopropyl alcohol, n-propyl alcohol, isobutyl alcohol, n-butyl alcohol, benzyl alcohol, ethylene glycol monomethyl ether, propylene glycol monomethyl ether, diethylene glycol monomethyl ether and diacetone alcohol; ketones, including acetone, methyl ethyl ketone, methyl isobutyl ketone, methyl amyl ketone, cyclohexanone and isophorone; aromatic hydrocarbons, including toluene, xylene, ethylbenzene and mesitylene; esters, including methyl acetate, ethyl acetate, ethylene glycol monomethyl ether acetate and 3-methoxybutyl acetate; and aliphatic hydrocarbons, including hexane, heptane, cyclohexane and methylcyclohexane. These solvents can be used singly or in combinations of two or more.

When the adhesive composition is a solution or a dispersion (resin varnish) including a solvent, the application to the base film and the formation of the adhesive layer can be smoothly carried out to readily obtain an adhesive layer having a desired thickness.

When the adhesive composition includes a solvent, the solid concentration is preferably in the range of 3 to 80% by mass, and more preferably 10 to 50% by mass, from the viewpoint of workability including formation of the adhesive layer. If the solid concentration is 80% by mass or less, a solution with a suitable viscosity can be obtained to facilitate uniform coating.

As a more specific embodiment of the method for producing the adhesive layer, a B-stage adhesive layer can be formed by coating a surface of a base film with a resin varnish containing the above-mentioned adhesive composition and a solvent to form a resin varnish layer, and then removing the solvent from the resin varnish layer. As used herein, adhesive layer in B-stage refers to a semi-cured state in which the adhesive composition is uncured or part of the adhesive composition has started to cure, so that the curing of the adhesive composition further proceeds by heating or the like.

Here, the method of applying the resin varnish on the base film is not particularly limited, and can be appropriately selected according to the intended purpose. Examples of the method include a spray method, a spin coating method, a dip method, a roll coating method, a blade coating method, a doctor roll method, a doctor blade method, a curtain coating method, a slit coating method, a screen printing method, an inkjet method and a dispensing method.

The B-stage adhesive layer can be further heated, for example to form a cured adhesive layer.

<Properties of Adhesive Layer>

The adhesive layer of the present invention obtained by curing the adhesive composition preferably has an adhesive layer relative permittivity (εr) of 3.5 or less and a dielectric loss tangent (tan δ) of 0.01 or less when measured at a frequency of 28 GHz.

If the relative permittivity is 3.5 or less and the dielectric loss tangent is 0.01 or less, the adhesive layer can be suitably used even for FPC-related products with strict requirements for electrical properties.

The relative permittivity and the dielectric loss tangent can be adjusted according to the type and content of the adhesive components, the type of the base film, and the like, and therefore various configurations of laminate can be set according to the application.

[Relative Permittivity and Dielectric Loss Tangent]

The relative permittivity and dielectric loss tangent of the adhesive layer can be measured using a network analyzer MS46122B (manufactured by Anritsu Corporation) and an open resonator Fabry-Perot DPS-03 (manufactured by KEYCOM Corporation) by an open resonator method under the conditions of a temperature of 23° C. and a frequency of 28 GHz.

(Laminate)

The laminate of the present invention includes a base film and the above-mentioned adhesive layer on at least one surface of the base film.

<Base Film>

The base film used in the present invention can be selected according to the laminate application. For example, when the laminate is to be used as a coverlay film or a copper-clad laminate (CCL), examples of the base film include a polyimide film, a polyether ether ketone film, a polyphenylene sulfide film, an aramid film, a polyethylene naphthalate film and a liquid crystal polymer film. Among these, a polyimide film, a polyether ether ketone (PEEK) film, a polyethylene naphthalate film and a liquid crystal polymer film are preferable from the viewpoint of adhesion properties and electrical properties.

Further, when the laminate of the present invention is to be used as a bonding sheet, the base film needs to be a release film, and examples thereof include a polyethylene terephthalate film, a polyethylene film, a polypropylene film, silicone-treated release paper, polyolefin resin-coated paper, a TPX (polymethylpentene) film and a fluororesin film.

When the laminate of the present invention is to be used as a shield film, the base film needs to be a film having an electromagnetic wave shielding ability, and examples thereof include a laminate of a protective insulating layer and a metal foil.

(Coverlay Film)

An example of a preferable embodiment of the laminate according to the present invention is a coverlay film.

For example, when producing an FPC, a laminate having an adhesive layer called a “coverlay film” is usually used to protect the wiring portion. This coverlay film includes an insulating resin layer and an adhesive layer formed on the surface thereof.

The coverlay film is a laminate in which the above-mentioned adhesive layer is formed on at least one surface of the above-mentioned base film, and it is generally difficult to separate the base film and the adhesive layer.

The thickness of the base film included in the coverlay film is preferably 5 to 100 μm, more preferably 5 to 50 μm, and further preferably 5 to 30 μm. When the thickness of the base film is equal to or less than this upper limit, a thinner coverlay film can be made. If the thickness of the base film is equal to or more than this lower limit, the printed circuit board can be designed easily and handling is also good.

The coverlay film can be produced by, for example, coating a surface of the above-mentioned base film with a resin varnish containing the above-mentioned adhesive composition and a solvent to form a resin varnish layer, and then removing the solvent from the resin varnish layer to produce a coverlay film in which a B-stage adhesive layer is formed.

The drying temperature when removing the solvent is preferably 40 to 250° C., and more preferably 70 to 170° C.

The drying is carried out by passing the laminate having the adhesive composition applied thereon through a furnace in which hot air drying, far infrared heating, high-frequency induction heating or the like is carried out.

Further, optionally, a release film can be laminated onto the surface of the adhesive layer for storage and the like. Examples of the usable release film include those known in the art, including a polyethylene terephthalate film, a polyethylene film, a polypropylene film, silicone-treated release paper, polyolefin resin-coated paper, a TPX film and a fluororesin film.

Since the coverlay film according to the present invention uses the low-dielectric adhesive composition of the present invention, high-speed transmission by electronic devices is possible, and adhesive stability with electronic devices is also excellent.

(Bonding Sheet)

An example of a preferable embodiment of the laminate according to the present invention is a bonding sheet.

The bonding sheet includes the above-mentioned adhesive layer formed on the surface of a release film (base film). In another embodiment of the bonding sheet, the adhesive layer can be incorporated between two release films. The release film is peeled off when the bonding sheet is used. The same release films as those described above in the section (Coverlay film) can be used.

The thickness of the base film included in the bonding sheet is preferably 5 to 100 μm, more preferably 25 to 75 μm, and further preferably 38 to 50 μm. When the thickness of the base film is within this range, the bonding sheet can be easily produced and handling is also good.

Examples of the method for producing the bonding sheet include a method in which the surface of a release film is coated with a resin varnish containing the above-mentioned adhesive composition and a solvent, and drying is performed in the same manner as in the case of the coverlay film.

Since the bonding sheet according to the present invention uses the low-dielectric adhesive composition of the present invention, high-speed transmission by electronic devices is possible, and adhesive stability with electronic devices is also excellent.

(Copper-Clad Laminate (CCL))

An example of a preferable embodiment of the laminate according to the present invention is a copper-clad laminate in which a copper foil is bonded to an adhesive layer in the laminate of the present invention.

The copper-clad laminate, which is formed by bonding a copper foil onto the above-mentioned laminate, is composed of, for example, a base film, an adhesive layer and a copper foil, in that order. The adhesive layer and the copper foil can be formed on both sides of the base film.

The adhesive composition used in the present invention also has excellent adhesion properties with articles including copper.

Since the copper-clad laminate according to the present invention uses the low-dielectric adhesive composition of the present invention, high-speed transmission by electronic devices is possible and the adhesive stability is excellent.

Examples of the method for producing the copper-clad laminate include a method in which the adhesive layer of the above-mentioned laminate and a copper foil are brought into surface contact, heat laminating is performed at 80° C. to 150° C., and then the adhesive layer is cured by after-curing. The after-curing conditions can be, for example, 100° C. to 200° C. for 30 minutes to 4 hours in an inert gas atmosphere. The copper foil is not particularly limited, and an electrolytic copper foil, a rolled copper foil and the like can be used.

(Printed Circuit Board)

An example of a preferable embodiment of the laminate according to the present invention is a printed circuit board in which copper wiring is bonded to an adhesive layer in the laminate of the present invention.

The printed circuit board is obtained by forming an electronic circuit on the above-mentioned copper-clad laminate.

The printed circuit board, which is formed by using the above-mentioned laminate and bonding a base film and copper wiring, is composed of a base film, an adhesive layer and copper wiring, in that order. The adhesive layer and the copper wiring can be formed on both sides of the base film.

The printed circuit board is produced by, for example, sticking a coverlay film onto the surface having the wiring portion with the adhesive layer arranged between the coverlay film and the surface by heat pressing or the like.

Since the printed circuit board according to the present invention uses the low-dielectric adhesive composition of the present invention, high-speed transmission by electronic devices is possible and the adhesive stability is excellent.

Examples of the method for producing the printed circuit board according to the present invention include a method in which the adhesive layer of the above-mentioned laminate and copper wiring are brought into contact, heat laminating is performed at 80° C. to 150° C., and then the adhesive layer is cured by after-curing. The after-curing conditions can be, for example, 100° C. to 200° C. for 30 minutes to 4 hours. The shape of the copper wiring is not particularly limited, and an appropriate shape and the like can be selected as desired.

(Shield Film)

An example of a preferable embodiment of the laminate according to the present invention a shield film.

The shield film is a film for shielding various electronic devices in order to cut electromagnetic noise that can affect and cause various electronic devices, including computers, mobile phones, analytical devices and the like, to malfunction. Another name for a shield film is electromagnetic wave shield film.

The electromagnetic wave shield film is formed by, for example, laminating an insulating resin layer, a metal layer, and the adhesive layer of the present invention, in that order.

Since the shield film according to the present invention uses the low-dielectric adhesive composition of the present invention, high-speed transmission by electronic devices is possible, and adhesive stability with electronic devices is also excellent.

(Printed Circuit Board Provided with a Shield Film)

An example of a preferable embodiment of the laminate according to the present invention is a printed circuit board provided with a shield film.

A printed circuit board provided with a shield film is formed by sticking the above-mentioned electromagnetic wave shield film on a printed circuit board having a printed circuit provided on at least one side of the substrate.

The printed circuit board provided with a shield film has, for example, a printed circuit board, an insulating film adjacent to the surface of the printed circuit board on the side where the printed circuit is provided, and the above-mentioned electromagnetic wave shield film.

Since the printed circuit board provided with a shield film according to the present invention uses the low-dielectric adhesive composition of the present invention, high-speed transmission by electronic devices is possible and the adhesive stability is excellent.

### EXAMPLES

The present invention will now be described in more detail with reference to the following Examples, but the scope of the present invention is not limited to these Examples. In the following, unless otherwise specified, parts and % are based on mass.

(Amino Group-Containing Styrene-Based Elastomer)

An elastomer with the trade name “Tuftec MP10” (amine-modified styrene-ethylene butylene-styrene copolymer) manufactured by Asahi Kasei Corporation was used. The styrene/ethylene butylene ratio of this copolymer is 30/70 and the weight average molecular weight is 78,000. The total amount of nitrogen contained in this copolymer is 426 ppm.

(Amino Group-Containing Styrene-Based Elastomer)

An elastomer with the trade name “Tuftec MPLH-01” (amine-modified styrene-ethylene butylene-styrene copolymer) manufactured by Asahi Kasei Corporation was used. The styrene/ethylene butylene ratio of this copolymer is 20/80 and the weight average molecular weight is 100,000. The total amount of nitrogen contained in this copolymer is 432 ppm.

### (Amino Group-Containing Styrene-Based Elastomer)

An elastomer with the trade name “Tuftec MPHF-02” (amine-modified styrene-ethylene butylene-styrene copolymer) manufactured by Asahi Kasei Corporation was used. The styrene/ethylene butylene ratio of this copolymer is 30/70 and the weight average molecular weight is 68,000. The total amount of nitrogen contained in this copolymer is 496 ppm.

### (Carboxy Group-Containing Styrene-Based Elastomer)

An elastomer with the trade name “Tuftec M1911” (maleic acid-modified styrene-ethylene butylene-styrene copolymer) manufactured by Asahi Kasei Corporation was used. The acid value of this copolymer is 2 mg KOH/g, the styrene/ethylene butylene ratio is 30/70, and the weight average molecular weight is 69,000.

### (Bismaleimide Resin)

As the bismaleimide resin, a bismaleimide resin with the trade name “SKL-3000-T50” (softening point of 60° C.) manufactured by Shin-Etsu Chemical Co., Ltd. was used.

### (Epoxy Resin)

As the epoxy resin, an epoxy resin with the trade name “YX7700” (softening point of 65° C.) manufactured by Mitsubishi Chemical Corporation, which is a novolak type epoxy resin, was used.

### (Epoxy Resin)

As the epoxy resin, an epoxy resin with the trade name “jER604” (liquid epoxy) manufactured by Mitsubishi Chemical Corporation, which is a glycidylamine type epoxy resin, was used.

### (Perbutyl E)

As the organic peroxide, an organic peroxide with the trade name “Perbutyl E,” which is a peroxy ester manufactured by NOF Corporation, was used.

### (Solvent)

A mixed solvent composed of toluene and methyl ethyl ketone (mass ratio=90:10) was used.

### (Base Film)

As the base film, “Shin-Etsu Sepla Film PEEK” (polyether ether ketone, thickness of 50 μm) manufactured by Shin-Etsu Polymer Co., Ltd. was used.

### (Electrolytic Copper Foil)

As the electrolytic copper foil, “TQ-M7-VSP” (electrolytic copper foil, thickness of 12 μm, glossy surface Rz of 1.27 μm, glossy surface Ra of 0.197 μm, glossy surface Rsm of 12.95 μm) manufactured by Mitsui Mining & Smelting Co., Ltd. was used. The surface roughness of the glossy surface is a value obtained by measuring a roughness curve using a laser microscope and calculating the surface roughness from the roughness curve based on JIS B 0601: 2013 (ISO 4287: 1997 Amd. 1: 2009).

### (Release Film)

As the release film, NP75SA (silicone release PET film, 50 μm) manufactured by Panac Co., Ltd. was used.

(Measurement of Nitrogen Content)

The total amount of nitrogen contained in the amino group-containing styrene-based elastomer used in the Examples was determined by the following method.

### <Measurement Method>

The total amount of nitrogen was determined according to JIS-K2609 using a trace nitrogen analyzer, model ND-100 (manufactured by Mitsubishi Chemical Corporation).

### Example 1

A resin varnish having a solid content concentration of 20% by mass was prepared by adding each of the components shown in Table 1 constituting the adhesive layer in the ratio shown in Table 1, and dissolving the components in a solvent.

The surface of the base film was subjected to a corona treatment.

The resin varnish was applied to the surface of the base film, and dried in an oven at 110° C. for 4 minutes. Toluene was volatilized to form an adhesive layer, whereby a base film having an adhesive was obtained. The adhesive layer of the adhesive laminate was placed so as to be in contact with the glossy surface of an electrolytic copper foil, and heat laminating was performed at 120° C. to obtain a pre-curing adhesive laminate. The pre-curing adhesive laminate was then subjected to after-curing for 60 minutes at 150° C. to cure the adhesive layer, whereby a cured adhesive laminate was obtained.

The peeling force (N/cm) between the electrolytic copper foil and the base film of the pre-curing adhesive laminate and the cured adhesive laminate of Example 1 was measured.

[Peeling Force (N/Cm)]

The peeling force was measured by cutting the pre-curing adhesive laminate and the cured adhesive laminate to obtain a test piece having a width of 25 mm, and then measuring the peeling strength when the electrolytic copper foil is peeled from the base film having an adhesive fixed to a support at a peeling angle of 180° at a peeling rate of 0.3 m/min in accordance with JIS 20237: 2009 (pressure-sensitive adhesive tape/pressure-sensitive adhesive sheet test method).

The relative permittivity and dielectric loss tangent at a frequency of 28 GHz of the adhesive layer in the laminate of Example 1 were also measured.

[Relative Permittivity and Dielectric Loss Tangent]

The relative permittivity and dielectric loss tangent of the adhesive layer were measured using a network analyzer MS46122B (manufactured by Anritsu Corporation) and an open resonator Fabry-Perot DPS-03 (manufactured by KEYCOM Corporation) by an open resonator method under the conditions of a temperature of 23° C. and a frequency of 28 GHz. The measurement sample was formed by applying a resin varnish on the release film with a roll, then placing the film provided with a coating film in an oven, and drying at 110° C. for 4 minutes to form a B-stage adhesive layer (thickness of 50 μm). Next, the adhesive layer was heat-laminated at 120° C. such that its adhesive surfaces were in contact with each other to form a pre-curing adhesive film (thickness of 100 μm). This pre-curing adhesive film (thickness of 100 μm) was placed in an oven and heat-cured at 150° C. for 60 minutes to prepare a cured adhesive film (100 mm×100 mm). The release film was peeled from the cured adhesive film, and the relative permittivity and dielectric loss tangent of the adhesive layer were measured.

The solvent resistance and the like of the adhesive layer in the laminate of Example 1 were also evaluated.

[Solvent Resistance]

A solvent resistance (cleaning solvent immersion) test was performed by cutting the cured adhesive laminate of Example 1 (this laminate is a laminate in which an electrolytic copper foil is laminated on a base film having an adhesive as described above) into a 30×30 mm test piece, and immersing the test piece in toluene for 3 hours.

The solvent resistance of the copper-clad laminate (CCL) having the adhesive layer of the present invention was evaluated according to the following evaluation criteria. A higher crosslink density of the adhesive layer indicates a higher peeling force and better solvent resistance.

A No peeling occurs, and solvent resistance is very good.
B Some peeling can be seen at the corners, and solvent resistance is good.
C Peeling can also be seen at the edges, and solvent resistance is poor.

[Acid Resistance]

An acid resistance test was performed by cutting the cured adhesive laminate of Example 1 into a 30×30 mm test piece, and immersing the test piece in 10% sulfuric acid aqueous solution for 3 hours.

The acid resistance of the copper-clad laminate (CCL) having the adhesive layer of the present invention was evaluated according to the following evaluation criteria.

A No peeling occurs, and acid resistance is very good.
B Some peeling can be seen at the corners, and acid resistance is good.
C Peeling can also be seen at the edges, and acid resistance is poor.

[Base Resistance]

A base resistance test was performed by cutting the cured adhesive laminate of Example 1 into a 30×30 mm test piece, and immersing the test piece in 10% sodium hydroxide aqueous solution for 3 hours.

The base resistance of the copper-clad laminate (CCL) having the adhesive layer of the present invention was evaluated according to the following evaluation criteria.

A No peeling occurs, and base resistance is very good.
B Some peeling can be seen at the corners, and base resistance is good.
C Peeling can also be seen at the edges, and base resistance is poor.

The results of each measurement are shown in Table 1.

### Examples 2 to 12

The laminated bodies of Examples 2 to 12 were prepared in the same manner as in Example 1 except that the types and amounts to be blended of the components constituting the adhesive layer were changed in Example 1 as shown in Table 1.

The prepared laminated bodies were evaluated in the same manner as in Example 1.

The results are shown in Table 1.

### Comparative Examples 1 to 6

The laminated bodies of Comparative Examples 1 to 6 were prepared in the same manner as in Example 1 except that the types and amounts to be blended of the components constituting the adhesive layer were changed in Example 1 as shown in Table 1.

The prepared laminated bodies were evaluated in the same manner as in Example 1.

The results are shown in Table 1.

TABLE 1

| | | | | | | | | | Peeling |
|---|---|---|---|---|---|---|---|---|---|
| | Components Constituting Adhesive Layer | | | | | | | | Force (N/cm) |
| | | | | | SKL- | | | | 120° C. |
| | MP10 | MPLH-01 | MPHF-02 | M1911 | 3000-T50 | YX7700 | jER 604 | Perbutyl E | Lamination |
| Example 1 | 70.0 | | | | 20.0 | 10.0 | | | 3.0 |
| Example 2 | 70.0 | | | | 25.0 | 5.0 | | | 3.2 |
| Example 3 | 50.0 | | | | 45.0 | 5.0 | | | 3.5 |
| Example 4 | 30.0 | | | | 65.0 | 5.0 | | | 4.0 |
| Example 5 | 50.0 | | | | 45.0 | | 5.0 | | 4.5 |
| Example 6 | 75.0 | | | | 25.0 | | | 3 | 3.2 |
| Example 7 | 55.0 | | | | 45.0 | | | 3 | 3.3 |
| Example 8 | 35.0 | | | | 65.0 | | | 3 | 3.7 |
| Example 9 | | | | 70.0 | 25.0 | | 5.0 | | 3.4 |
| Example 10 | | 50.0 | | | 45.0 | 5.0 | | | 3.2 |
| Example 11 | | | 50.0 | | 45.0 | 5.0 | | | 3.4 |
| Example 12 | | | | 70.0 | 25.0 | 5.0 | | | 3.0 |
| Comparative | 95.0 | | | | | 5.0 | | | 1.5 |
| Example 1 | | | | | | | | | |
| Comparative | | | | 95.0 | | 5.0 | | | 2.1 |
| Example 2 | | | | | | | | | |
| Comparative | 100 | | | | | | | 3.0 | 1.3 |
| Example 3 | | | | | | | | | |
| Comparative | | | | | 100 | | | 3.0 | 0.4 |
| Example 4 | | | | | | | | | |
| Comparative | 70.0 | | | | | | 30.0 | | 3.1 |
| Example 5 | | | | | | | | | |
| Comparative | 70.0 | | | | | 30.0 | | | 2.6 |
| Example 6 | | | | | | | | | |

| | Peeling | | | | | |
|---|---|---|---|---|---|---|
| | Force (N/cm) | Electrical Properties | | Solvent Resistance etc. | | |
| | 150° C. | Relative | Dielectric | Solvent | Acid | Base |
| | Curing | permittivity | loss tangent | resistance | resistance | resistance |
| Example 1 | 9.3 | 2.52 | 0.0074 | B | A | A |
| Example 2 | 10.3 | 2.44 | 0.0041 | B | A | A |
| Example 3 | 9.8 | 2.45 | 0.0040 | A | A | A |
| Example 4 | 10.8 | 2.45 | 0.0043 | A | A | A |
| Example 5 | 9.5 | 2.55 | 0.0053 | A | A | A |
| Example 6 | 9.9 | 2.44 | 0.0025 | B | A | A |
| Example 7 | 8.9 | 2.44 | 0.0030 | B | A | A |
| Example 8 | 9.5 | 2.45 | 0.0034 | A | A | A |
| Example 9 | 11.3 | 2.53 | 0.0046 | B | B | B |
| Example 10 | 9.4 | 2.52 | 0.0048 | A | A | A |
| Example 11 | 10.4 | 2.48 | 0.0045 | A | A | A |
| Example 12 | 11.5 | 2.45 | 0.0040 | B | B | B |
| Comparative | 13.5 | 2.33 | 0.0042 | B | B | B |
| Example 1 | | | | | | |
| Comparative | 9.5 | 2.45 | 0.0047 | C | C | C |
| Example 2 | | | | | | |
| Comparative | 12.0 | 2.30 | 0.0010 | C | B | C |
| Example 3 | | | | | | |
| Comparative | 2.3 | 2.48 | 0.0039 | C | C | C |
| Example 4 | | | | | | |
| Comparative | 5.4 | 2.61 | 0.0266 | C | C | C |
| Example 5 | | | | | | |
| Comparative | 6.3 | 2.60 | 0.0209 | C | C | C |
| Example 6 | | | | | | |

As shown by Examples 1 to 12, the adhesive layer composed of the adhesive composition of the present invention has excellent adhesiveness (adhesion properties) after heat curing, as well as excellent adhesiveness (adhesion properties) in the laminating step.

Further, the adhesive layer composed of the adhesive composition of the present invention exhibits excellent electrical properties (low relative permittivity and low dielectric loss tangent).

In addition, the adhesive layer composed of the adhesive composition of the present invention also has excellent solvent resistance.

This application claims priority from Japanese Patent Application No. 2019-231705, which is a Japanese patent application filed on Dec. 23, 2019, the entire contents of which are hereby incorporated herein.

### INDUSTRIAL APPLICABILITY

The laminate having an adhesive layer composed of the adhesive composition of the present invention can be suitably used in the production of FPC-related products for electronic devices, including smartphones, mobile phones, optical modules, digital cameras, game machines, laptop computers and medical instruments.

1. An adhesive composition comprising a bismaleimide resin and a styrene-based elastomer.

2. The adhesive composition according to claim 1, further comprising an epoxy resin.

3. The adhesive composition according to claim 2, wherein a content of the epoxy resin is 1 to 20 parts by mass based on 100 parts by mass of the adhesive composition.

4. The adhesive composition according to claim 1, further comprising an organic peroxide.

5. The adhesive composition according to claim 1, wherein the styrene-based elastomer is any one or both of an amino group-containing styrene-based elastomer and a carboxy group-containing styrene-based elastomer.

6. The adhesive composition according to claim 5, wherein a total amount of nitrogen in the amino group-containing styrene-based elastomer is 50 to 5,000 ppm.

7. The adhesive composition according to claim 2, wherein the epoxy resin has a softening point or a melting point of 90° C. or lower.

8. The adhesive composition according to claim 2, wherein the epoxy resin is a novolak type epoxy resin.

9. The adhesive composition according to claim 2, wherein the epoxy resin is a glycidylamine type epoxy resin.

10. The adhesive composition according to claim 2, wherein the epoxy resin is an epoxy compound of a styrene-butadiene block copolymer.

11. An adhesive layer obtained by curing the adhesive composition according to claim 1, wherein the adhesive layer has a relative permittivity of 3.5 or less and a dielectric loss tangent of 0.01 or less when measured at a frequency of 28 GHz.

12. A laminate comprising:
a base film; and
an adhesive layer composed of the adhesive composition according to claim 1.

13. The laminate according to claim 12, wherein the base film contains a polyether ether ketone (PEEK) resin.

14. A coverlay film provided with an adhesive layer, comprising the laminate according to claim 12.

15. A copper-clad laminate comprising the laminate according to claim 12.

16. A printed circuit board comprising the laminate according to claim 12.

17. A shield film comprising the laminate according to claim 12.

18. A printed circuit board provided with a shield film, comprising the laminate according to claim 12.
